(19) United States
(12) Patent Application Publication
(10) Pub. No.: US 2026/0143601 A1
(43) Pub. Date: May 21, 2026

(54) REINFORCED SUPPORT SHEET AND FOLDABLEDISPLAY DEVICE INCLUDING THE SAME

(71) Applicant: High Entropy Materials, Inc., Hsinchu City (TW)

(72) Inventor: JIEN-WEI YEH, Hsinchu City (TW)

(21) Appl. No.: 19/395,978

(22) Filed: Nov. 20, 2025

(30) Foreign Application Priority Data
Nov. 20, 2024 (TW) 113144584

(51) Int. Cl. H05K 5/02

(52) U.S. Cl. CPC H05K 5/0217

(57) ABSTRACT

A reinforced support sheet is disclosed. The reinforced support sheet can be integrated in a foldable display device for supporting a bottom surface of a display panel, and comprises a substrate and at least one wrinkle structure. Specifically, the wrinkle structure oppositely overlaps a foldable region of the display panel. Therefore, in case of the display panel being folded, a stress applied to the foldable region is buffered and/or attenuated by the wrinkle structure, thereby releasing and/or attenuating the residual strain force accumulated in the foldable region of the display panel. In addition, the wrinkle structure also enhances the reinforced support sheet’s strength and rigidity, such that the reinforced support sheet performs an outstanding effect on supporting the display panel.

### CROSS-REFERENCE TO RELATED APPLICATIONS

This This application claims the priority and benefit of Taiwan patent application No. 113144584, filed on November, 20, 2024, the entire contents of which are incorporated herein by reference.

### BACKGROUND OF THE INVENTION

### 1. Field of the Invention

The present invention relates to the technology filed of foldable display devices, and more particularly, to a reinforced support sheet and a foldable display device including the same.

### 2. Description of the Prior Art

It is known that various types of foldable smartphone, upending regular understanding of the commonly used smartphones, are developed so as to be launched on the market. For instance, U.S. patent No. 9,274,560 B2 has disclosed that a flexible display device with reference to FIG. 1. As FIG. 1 shows, the flexible display device 1a comprises a housing 10a that may be disposed in a flat state or a bent state, a supporting plate 14a coupled to an inner surface of the housing 10a, and a flexible panel 15a attached to the supporting plate 14a. To be described in more detail, the housing 10a comprises a substrate 13a, a first side plate 11a and a second side plate 12a, in which the first side plate 11a is pivotally connected to one side of the substrate 13a, and the second side plate 12a is pivotally connected to another one side of the substrate 13a. According to practical experience, after repeatedly folding and unfolding the flexible display device 1a, there is at least one crease formed on the flexible panel 15a and/or the supporting plate 14a resulted from residual strain force accumulation. Seriously, expansion of the crease may cause the flexible panel 15a fail to conduct image displaying normally. On the other hand, there are a significant number of cracks formed so as to accumulated at the folding region of the supporting plate 14a, such that the supporting plate 14a may be broken due to the crack accumulation.

Accordingly, U.S. patent publication No. 2022/0199922 A1 has correspondingly disclosed a support substrate for addressing the drawback of the flexible display device 1a mentioned above. FIG. 2 illustrates a schematic stereo diagram of the support substrate disclosed by U.S. patent publication No. 2022/0199922 A1. As FIG. 2 shows, there are a plurality of pores 141b formed on a folding region of the support substrate 14b, and the plurality of pores 141b are lined up in N rows. To be more specific, the pores 141b lined up in i-th row all have a pore size smaller than that of the pores 141b lined up in (i+1)-th row. As such, the plurality of pores 141b perform an effect on releasing and/or attenuating the strain force formed during folding and/or unfolding the flexible display device 1a (as shown in FIG. 1) and accumulated the flexible panel 15a, eventually resulting in significantly cancelling the residual strain force accumulated in the flexible panel 15a. However, since any two said pores 141b are separated by connecting ribs with reference to FIG. 2, it is a pity that some of the connecting ribs may be broken after repeatedly folding and unfolding the flexible display device 1a (as shown in FIG. 1). Consequently, the rupture of some of the connecting ribs lead the strain force attenuating effect performed by the support substrate 14b to be declined. In addition, in serious case the broken connecting ribs may damage the flexible panel 15a stacked on the support substrate 14b.

According to above descriptions, it is easily understood that there is a room for improvement in the supporting plate 14a of FIG. 1 and the support substrate 14b of FIG. 2. In view of that, inventors of the present application have made great efforts to make inventive research and eventually provided a reinforced support sheet and a foldable display device including the same.

### SUMMARY OF THE INVENTION

The primary objective of the present invention is to provide a reinforced support sheet for application in a foldable display device. The reinforced support sheet is used to support a bottom surface of a display panel of the foldable display device, and comprises a substrate and at least one wrinkle structure, in which the wrinkle structure oppositely overlaps a foldable region of the display panel. Therefore, in case of the display panel being folded, a stress applied to the foldable region is buffered and/or attenuated by the wrinkle structure, thereby releasing and/or attenuating the residual strain force accumulated in the foldable region of the display panel. In addition, the wrinkle structure also enhances the reinforced support sheet’s strength and rigidity, such that the reinforced support sheet performs an outstanding effect on supporting the display panel.

In order to achieve the aforementioned objective, one embodiment of the reinforced support sheet is provided, which is adapted for integration in a foldable display device for supporting a display panel with N numbers of foldable regions, and comprises:

a substrate, being attached to the display panel through an adhesive layer; and

N numbers of wrinkle structures, being formed on the substrate; wherein N is a positive integer, and the N numbers of wrinkle structures oppositely overlaps the N numbers of foldable regions;

wherein each of the N numbers of wrinkle structures consists of a plurality of first protrusions humping on a first surface of the substrate and a plurality of second protrusions humping on a second surface of the substrate, and the second surface of the substrate is stuck to the display panel through the adhesive layer;

wherein the substrate and any two said first protrusions enclose a first recess, and the substrate and any two said second protrusions enclose a second recess;

wherein the adhesive layer is formed with a plurality of convexes thereon, and each of the plurality of convexes correspondingly received by one said second recess;

wherein there is a first spacing between the plurality of second protrusions and the display panel in case of the reinforced support sheet being attached to the display panel.

In one embodiment, said first protrusion and said second protrusion all have a cross-sectional shape selected from a group consisting of semicircle shape, convex shape, rectangular shape, trapezoid shape, and tapered shape.

In one embodiment, the substrate is fully covered by the N numbers of wrinkle structures.

In one embodiment, the substrate is made of a metal material, and has a thickness in a range between 10 μm and 60 μm.

In one embodiment, there is a second spacing between a peak of said first protrusion and the second surface of the display panel, and the second spacing is in a range between 10 μm and 1,000 μm.

In one embodiment, said first protrusion is provided with a plurality of holes thereon, and said convex received by one said second recess is further embedded in one said hole correspondingly.

In one embodiment, said second protrusion is provided with a plurality of holes thereon, and said convex that is received by one said second recess is further embedded in one said hole correspondingly.

In one optional embodiment, at least two reinforcement wrinkle structures are formed on the substrate, so as to surround the N numbers of wrinkle structures.

In another one optional embodiment, a plurality og reinforcement wrinkle structures are formed on the substrate, so as to surround the N numbers of wrinkle structures.

Moreover, another one embodiment of the reinforced support sheet is provided, which is adapted for integration in a foldable display device for supporting a display panel with N numbers of foldable regions, and comprises:

a substrate, being attached to the display panel through an adhesive layer; and

N numbers of wrinkle structures, being formed on the substrate;

wherein N is a positive integer, and the N numbers of wrinkle structures oppositely overlaps the N numbers of foldable regions; wherein each of the N numbers of wrinkle structures consists of a plurality of first protrusions periodically humping on a first surface of the substrate and a plurality of second protrusions periodically humping on a second surface of the substrate, and the second surface of the substrate is stuck to the display panel through the adhesive layer;

wherein the substrate and any two said first protrusions enclose a first recess, and the substrate and any two said second protrusions enclose a second recess;

wherein the adhesive layer is formed with a plurality of convexes thereon, and each of the plurality of convexes correspondingly received by one said second recess;

wherein the plurality of second protrusions are in proximity to the display panel in case of the reinforced support sheet being attached to the display panel.

In addition, further another embodiment of the reinforced support sheet is provided, which is adapted for integration in a foldable display device for supporting a display panel with N numbers of foldable regions, and comprises:

a substrate, being attached to the display panel through an adhesive layer; and

N numbers of wrinkle structures, being formed on the substrate;

wherein N is a positive integer, and the N numbers of wrinkle structures oppositely overlaps the N numbers of foldable regions;

wherein each of the N numbers of wrinkle structures consists of a plurality of first protrusions periodically humping on a first surface of the substrate and a plurality of second protrusions periodically humping on a second surface of the substrate, and the second surface of the substrate is stuck to the display panel through the adhesive layer;

wherein the substrate and any two said first protrusions enclose a first recess, the adhesive layer is formed with a plurality of convexes thereon, and each of the plurality of convexes correspondingly received by one said first recess;

wherein there is a spacing between the second surface of the substrate and the display panel in case of the reinforced support sheet being attached to the display panel.

On the other hand, an embodiment of a foldable display device is also provided, which comprises:

a housing case having a top opening;

a display panel, being accommodated in the housing case, wherein a display area of the display panel is exposed from the housing case through the top opening;

a control circuit module of the display panel, being accommodated in the housing case; and

the reinforced support sheet according to the present invention, being attached to the display panel.

### BRIEF DESCRIPTION OF THE DRAWINGS

The invention as well as a preferred mode of use and advantages thereof will be best understood by referring to the following detailed description of an illustrative embodiment in conjunction with the accompanying drawings, wherein:

FIG. 1 shows a cross-sectional view of a flexible display device disclosed by U.S. patent No. 9,274,560 B2.

FIG. 2 shows a schematic stereo diagram of a support substrate disclosed by U.S. patent publication No. 2022/0199922 A1.

FIG. 3 shows a first schematic stereo diagram of a reinforced support sheet according to a first embodiment of the present invention.

FIG. 4 shows a second schematic stereo diagram of the reinforced support sheet according to the first embodiment of the present invention.

FIG. 5 shows a first cross-sectional view of a wrinkle structure shown in FIG. 3.

FIG. 6 shows a second cross-sectional view of the wrinkle structure shown in FIG. 3.

FIG. 7 shows a third cross-sectional view of the wrinkle structure shown in FIG. 3.

FIG. 8 shows a third schematic stereo diagram of the reinforced support sheet according to the first embodiment of the present invention.

FIG. 9 shows a first cross-sectional view of the wrinkle structure shown in FIG. 8.

FIG. 10 shows a second cross-sectional view of the wrinkle structure shown in FIG. 8.

FIG. 11 shows a third cross-sectional view of the wrinkle structure shown in FIG. 8.

FIG. 12 shows a first schematic stereo diagram of the reinforced support sheet according to a second embodiment of the present invention.

FIG. 13 shows a first cross-sectional view of the wrinkle structure shown in FIG. 12.

FIG. 14 shows a second cross-sectional view of the wrinkle structure shown in FIG. 12.

FIG. 15 shows a third cross-sectional view of the wrinkle structure shown in FIG. 12.

FIG. 16 shows a second schematic stereo diagram of the reinforced support sheet according to the second embodiment of the present invention.

FIG. 17 shows a first cross-sectional view of the wrinkle structure shown in FIG. 16.

FIG. 18 shows a second cross-sectional view of the wrinkle structure shown in FIG. 16.

FIG. 19 shows a third cross-sectional view of the wrinkle structure shown in FIG. 16.

FIG. 20 shows a first schematic stereo diagram of the reinforced support sheet according to a third embodiment of the present invention.

FIG. 21 shows a first cross-sectional view of the wrinkle structure shown in FIG. 20.

FIG. 22 shows a second cross-sectional view of the wrinkle structure shown in FIG. 20.

FIG. 23 shows a third cross-sectional view of the wrinkle structure shown in FIG. 20.

FIG. 24 shows a second schematic stereo diagram of the reinforced support sheet according to the third embodiment of the present invention.

FIG. 25 shows a first cross-sectional view of the wrinkle structure shown in FIG. 24.

FIG. 26 shows a second cross-sectional view of the wrinkle structure shown in FIG. 24.

FIG. 27 shows a third cross-sectional view of the wrinkle structure shown in FIG. 24.

FIG. 28 shows a first schematic top view of the reinforced support sheet according to the present invention.

FIG. 29 shows a second schematic top view of the reinforced support sheet according to the present invention.

FIG. 30 shows a schematic top view of the reinforced support sheet according to a fourth embodiment of the present invention.

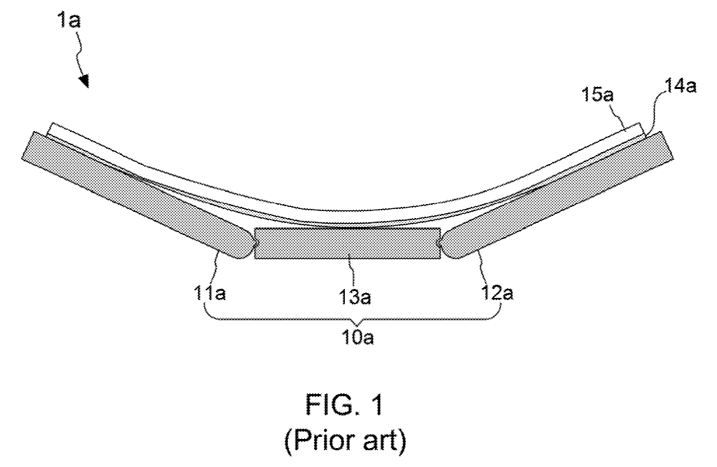

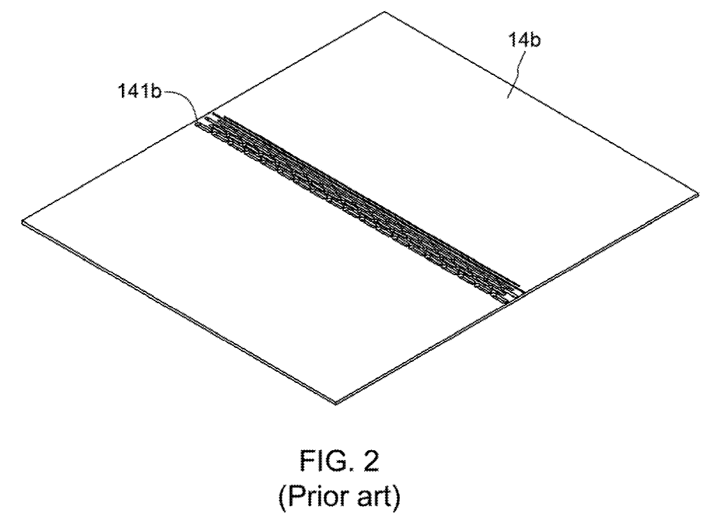

### DETAILED DESCRIPTION OF THE PREFERRED EMBODIMENTS

To more clearly describe a reinforced support sheet according to the present invention, embodiments of the present invention will be described in detail with reference to the attached drawings hereinafter.

### First embodiment

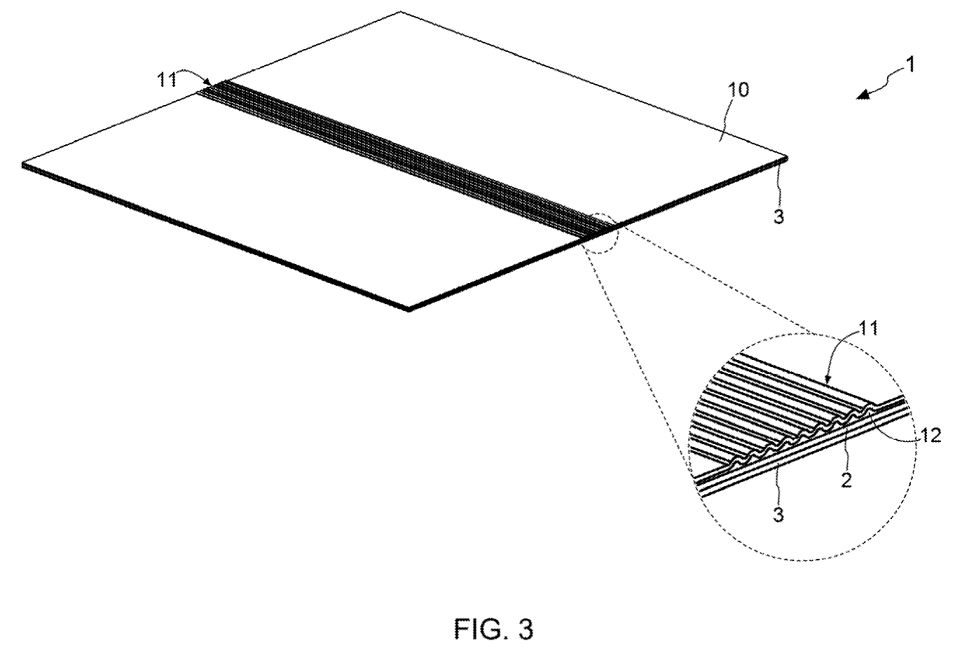

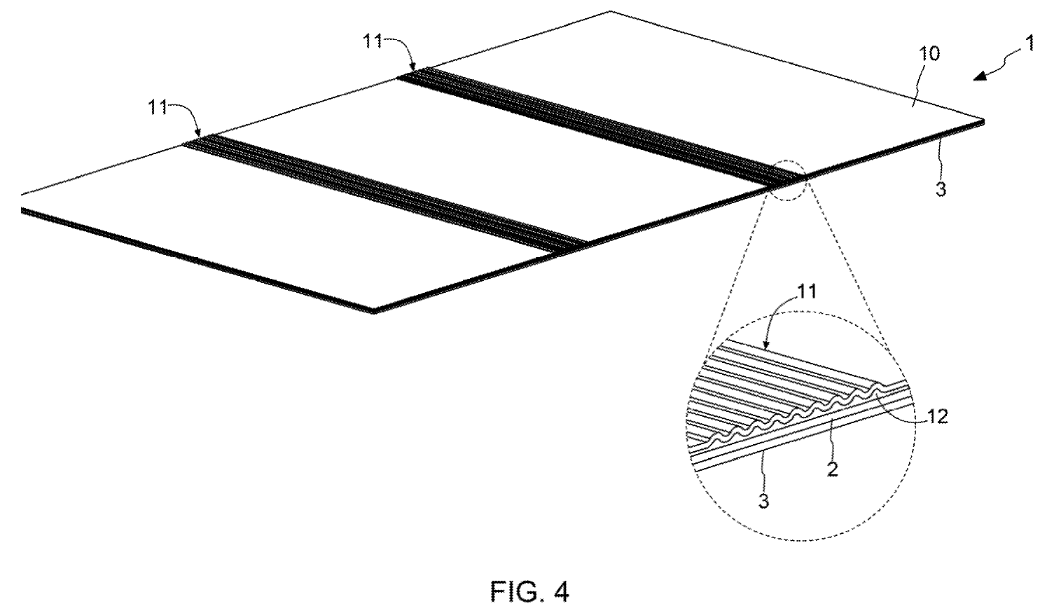

With reference to FIG. 3 and FIG. 4, there are illustrated two schematic stereo diagrams of a reinforced support sheet according to a first embodiment of the present invention. As FIG. 3 shows, the reinforced support sheet 1 is adapted for integration in a foldable display device for supporting a display panel 2 with N numbers of foldable regions, and comprises a substrate 10 and N numbers of wrinkle structures 11 formed on the substrate 10. To be more specific, the substrate 10 is attached to a first surface of the display panel 2 through an adhesive layer 12, so as to make the N numbers of wrinkle structures 11 oppositely overlap the N numbers of foldable regions. It is aware of that N represents the number of times that the foldable display device can be folded. Taking Samsung Galaxy Z fold 4 as an example of the foldable display device, N is positive integer “1”. In this case, as FIG. 3 shows that the display panel 2 has one foldable region, and the substrate 10 is formed with one said wrinkle structure 11 thereon. Furthermore, Taking Huawei Mate XT as another example of the foldable display device, N is positive integer “2”. In this case, as FIG. 4 shows that the display panel 2 has two foldable regions, and two said wrinkle structures 11 are formed on the substrate 10. Moreover, it is worth noticing that there is an optical protection sheet attached to a second surface of the display panel 2 with reference to FIG. 3 and FIG. 4.

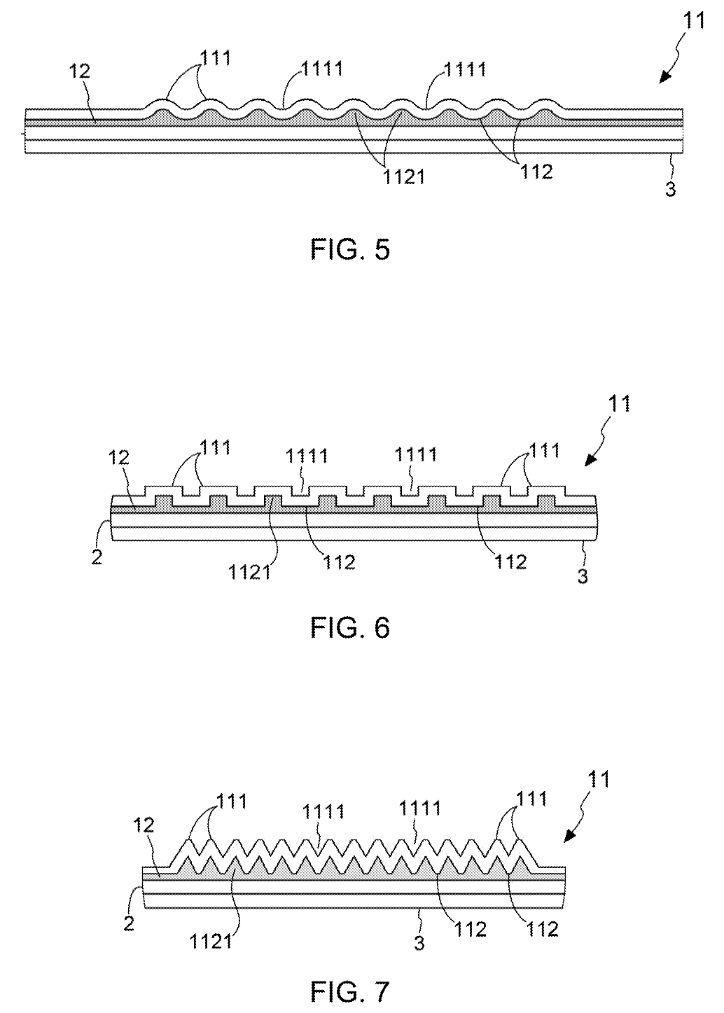

With reference to FIG. 5, FIG. 6 and FIG. 7 continuously, there are illustrated first, second and third cross-sectional views of the wrinkle structure 11 shown in FIG. 3. To be more specific, in first embodiment each of the N numbers of wrinkle structures 11 consists of a plurality of first protrusions 111 humping on a first surface of the substrate 10 and a plurality of second protrusions 112 humping on a second surface of the substrate 10, and the second surface of the substrate 10 is stuck to the display panel 2 through the adhesive layer 12. Moreover, it is aware of that said protrusion 111 and said second protrusion 112 all have a cross-sectional shape with reference to FIG. 3, FIG. 5, FIG. 6, and FIG. 7. In any practicable embodiments, the cross-sectional shape can be, but is not limited to semicircle shape, convex shape, rectangular shape, trapezoid shape, or tapered shape.

As described in more detail below, the substrate 10 is made of a metal material, and has a thickness in a range between 10 μm and 60 μm. For instance, the metal material can be, but is not limited to copper alloy, aluminum alloy, titanium alloy, steel, medium-entropy alloy, or high-entropy alloy.

As FIG. 5, FIG. 6 and FIG. 7 show, the substrate 10 and any two said first protrusions 111 enclose a first recess 1111, the substrate 10 and any two said second protrusions 112 enclose a second recess 1121, and adhesive layer 12 is formed with a plurality of convexes thereon. Au such, there is a first spacing between the plurality of second protrusions 112 and the display panel 2 in case of the reinforced support sheet 1 being attached to the display panel 2, and each of the plurality of convexes correspondingly received by one said second recess 1121. It is worth further explaining that there is a second spacing between a peak of said first protrusion 111 and the second surface of the display panel 2, of which the second spacing is in a range between 10 μm and 1,000 μm.

As FIG. 5 shows, said first recess 1111 is a concave formed in the first surface of the substrate 10, and said second recess 1121 is also a concave formed in the second surface of the substrate 10. On the other hand, in FIG. 6 and FIG. 7 said first recess 1111 is enclosed by the first surface of the substrate 10 and two said first protrusions 111, thereby being formed on the first surface of the substrate 10. Similarly, said second recess 1121 is enclosed by the second surface of the substrate 10 and two said second protrusions 112, so as to be formed on the second surface of the substrate 10.

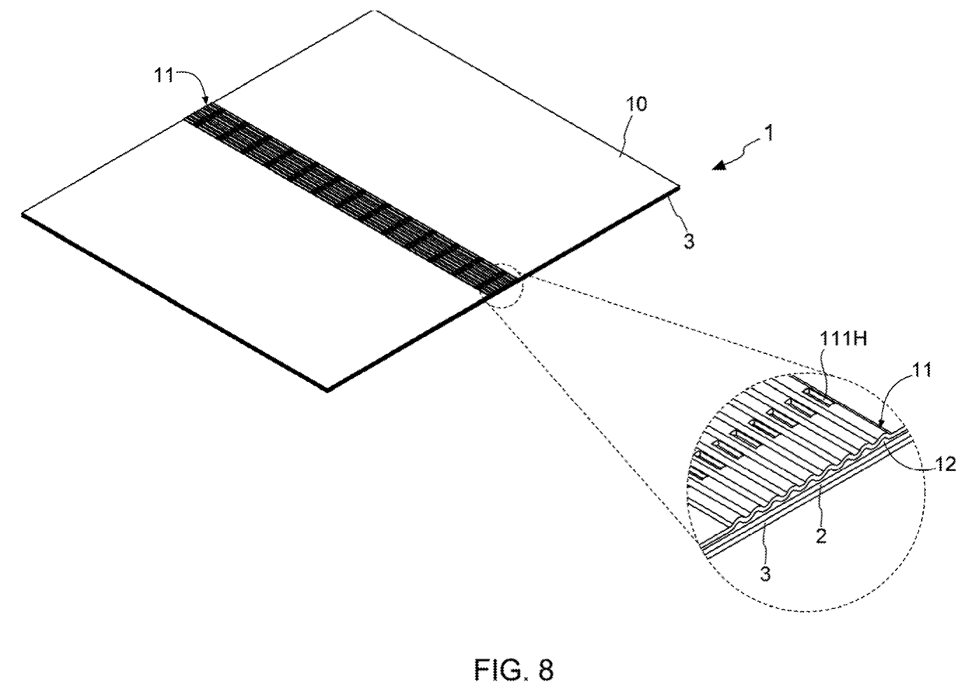

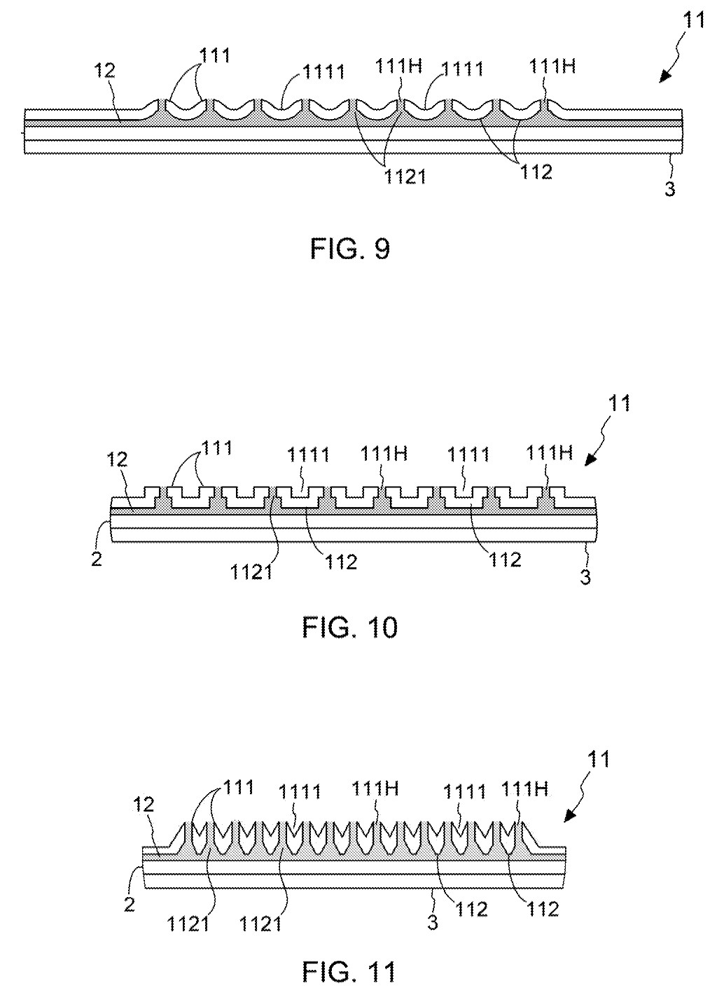

Furthermore, FIG. 8 illustrates a third schematic stereo diagram of the reinforced support sheet 1 according to the first embodiment of the present invention. Moreover, FIG. 9, FIG. 10 and FIG. 11 illustrate first, second and third cross-sectional views of the wrinkle structure 11 shown in FIG. 8. According to FIG. 8 and FIG. 9, it is aware of that in practical use each of the plurality of first protrusions 111 can be further provided with a plurality of holes 111H thereon, such that said convex received by one said second recess 1121 is further embedded in one said hole 111H correspondingly. Furthermore, it is also understood that, with reference to FIG. 9, FIG. 10 and FIG. 11, said protrusion 111 and said second protrusion 112 all have a cross-sectional shape, and the cross-sectional shape can be, but is not limited to semicircle shape, convex shape, rectangular shape, trapezoid shape, or tapered shape. In addition, it can be further noticeable that, said second recess 1121 formed on the second surface of the substrate 10 oppositely locates below said first recess 111 formed on the first surface of the substrate 10. As such, after the substrate 10 is attached to the display panel 2 through the adhesive layer 12, the plurality of convexes of the adhesive layer 12 are received by the plurality of second recess 1121 formed on the second surface of the substrate 10, respectively. Moreover, said convex received by one said second recess 1121 is further embedded in one said hole 111H correspondingly, thereby enhancing the adhesion strength between the substrate 10 and the display panel 2. As a result, adhesive failure is prevented from occurring between the display panel 2 and the reinforced support sheet 1 even if the display panel 2 is repeatedly folded and unfolded.

In another optional embodiment, it is also able to form a plurality of hole on each of the plurality of second protrusions 112. As such, after the substrate 10 is attached to the display panel 2 through the adhesive layer 12, the plurality of convexes of the adhesive layer 12 are received by the plurality of second recess 1121 formed on the second surface of the substrate 10, respectively. Moreover, said convex received by one said second recess 1121 is further embedded in one said hole 1correspondingly, thereby enhancing the adhesion strength between the substrate 10 and the display panel 2.

### Second embodiment

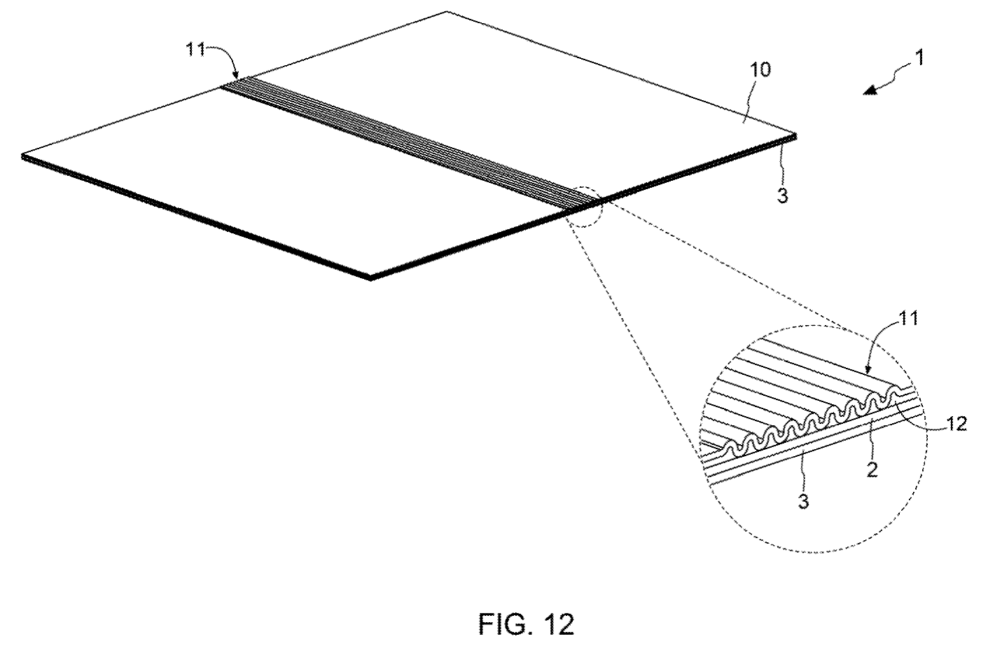

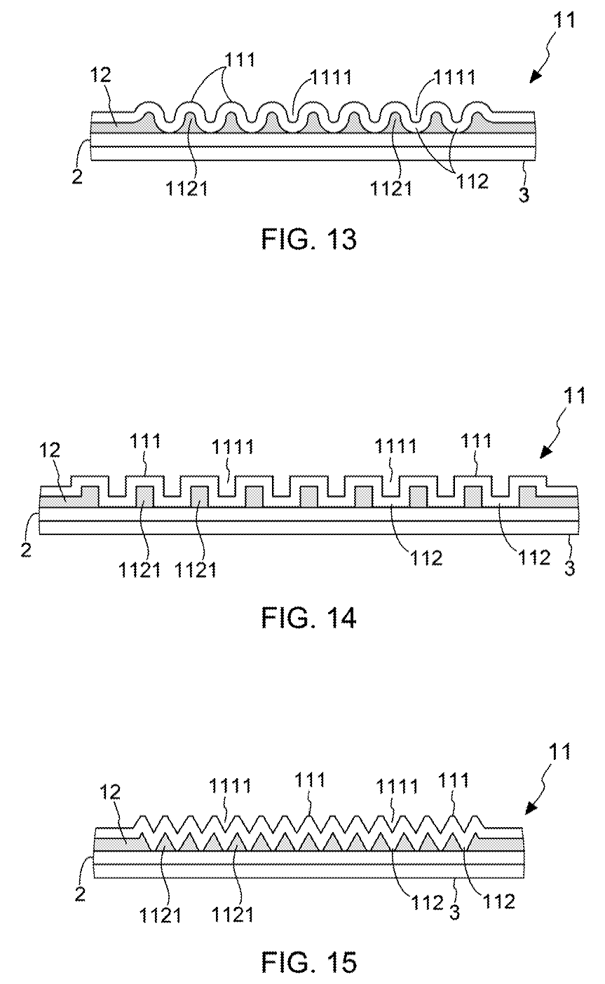

FIG. 12 illustrates a first schematic stereo diagram of the reinforced support sheet 1 according to a second embodiment of the present invention. Moreover, FIG. 13, FIG. 14 and FIG. 15 illustrate first, second and third cross-sectional view of the wrinkle structure shown in FIG. 12. As FIG. 12 and FIG. 13 show, in second embodiment the reinforced support sheet 1 also comprises a substrate 10, N numbers of wrinkle structures 11 formed on the substrate 10 and an adhesive layer 12, of which the adhesive layer 12 is formed with a plurality of convexes thereon. To be more specific, the wrinkle structure 11 comprises a plurality of first protrusions 111 and a plurality of second protrusions 112, of which the plurality of first protrusions 111 is formed on a first surface of the substrate 10, and the plurality of second protrusions 112 is formed on a second surface of the substrate 10. In addition, the substrate 10 is attached to a first surface of the display panel 2 through the adhesive layer 12, so as to make the N numbers of wrinkle structures 11 oppositely overlap the N numbers of foldable regions of the display panel 2. As described in more detail below, said protrusion 111 and said second protrusion 112 all have a cross-sectional shape with reference to FIG. 12, FIG. 13, FIG. 14, and FIG. 15. In any practicable embodiments, the cross-sectional shape can be, but is not limited to semicircle shape, convex shape, rectangular shape, trapezoid shape, or tapered shape.

To more specific, in second embodiment, the first surface of the substrate 10 and any two said first protrusions 111 enclose a first recess 1111, and the second surface of the substrates 10 and any two said second protrusions 112 enclose a second recess 1121. As such, after the reinforced support sheet 1 is attached to the display panel 2 by the substrate 10 thereof, the plurality of second protrusions 112 are in proximity to the display panel 2, and each of the plurality of convexes of the adhesive layer 12 correspondingly received by one said second recess 1121. On the other hand, FIG. 13, FIG. 14 and FIG. 15 also depict that there is a second spacing between a peak of said first protrusion 111 and the second surface 112 of the display panel 2, and the second spacing is in a range between 10 μm and 1,000 μm.

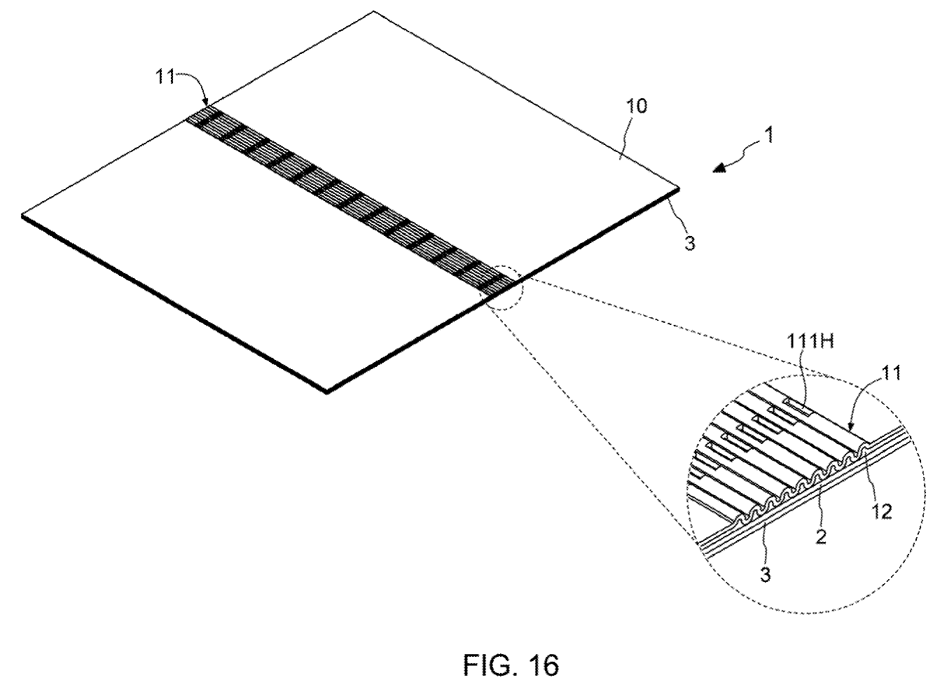

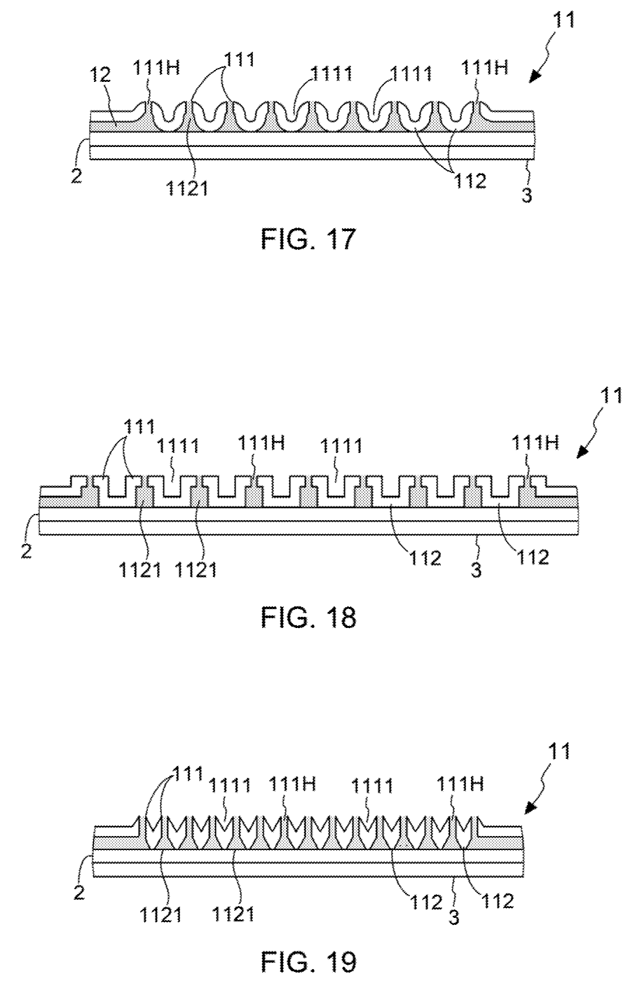

Furthermore, FIG. 16 illustrates a second schematic stereo diagram of the reinforced support sheet 1 according to the second embodiment of the present invention. Moreover, FIG. 17, FIG. 18 and FIG. 19 illustrate first, second and third cross-sectional views of the wrinkle structure 11 shown in FIG. 16. As FIG. 16, FIG. 17, FIG. 18, and FIG. 19 show, in second embodiment said protrusion 111 and said second protrusion 112 all have a cross-sectional shape, wherein the cross-sectional shape can be, but is not limited to semicircle shape, convex shape, rectangular shape, trapezoid shape, or tapered shape. In addition, it can also form a plurality of holes 111H on each of the plurality of first protrusions 111. As such, after the substrate 10 is attached to the display panel 2 through the adhesive layer 12, the plurality of convexes of the adhesive layer 12 are received by the plurality of second recess 1121 formed on the second surface of the substrate 10, respectively. Moreover, said convex received by one said second recess 1121 is further embedded in one said hole 111H correspondingly, thereby enhancing the adhesion strength between the substrate 10 and the display panel 2. As a result, adhesive failure is prevented from occurring between the display panel 2 and the reinforced support sheet 1 even if the display panel 2 is repeatedly folded and unfolded.

In another optional embodiment, it is also able to form a plurality of hole on each of the plurality of second protrusions 112. As such, after the substrate 10 is attached to the display panel 2 through the adhesive layer 12, the plurality of convexes of the adhesive layer 12 are received by the plurality of second recess 1121 formed on the second surface of the substrate 10, respectively. Moreover, said convex received by one said second recess 1121 is further embedded in one said hole 1 correspondingly, thereby enhancing the adhesion strength between the substrate 10 and the display panel 2.

### Third embodiment

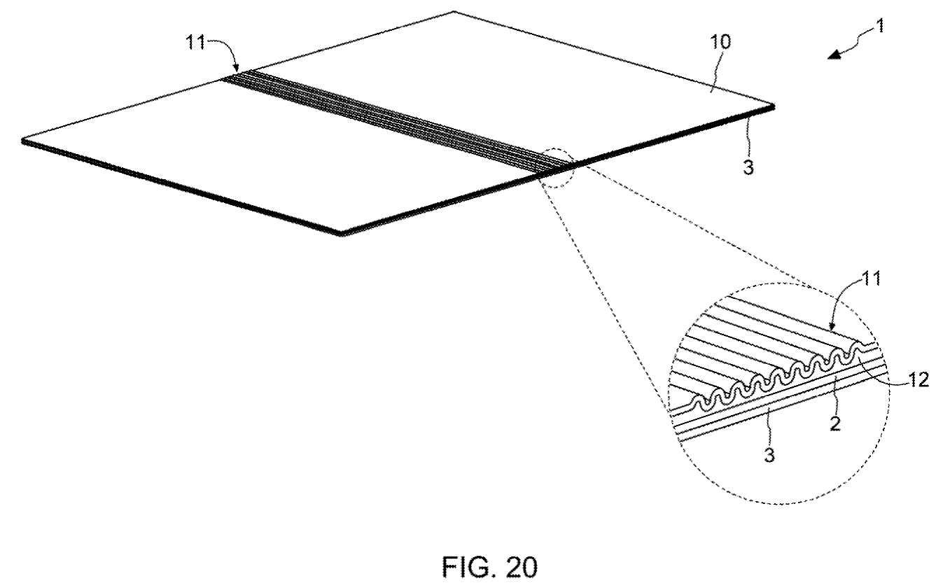

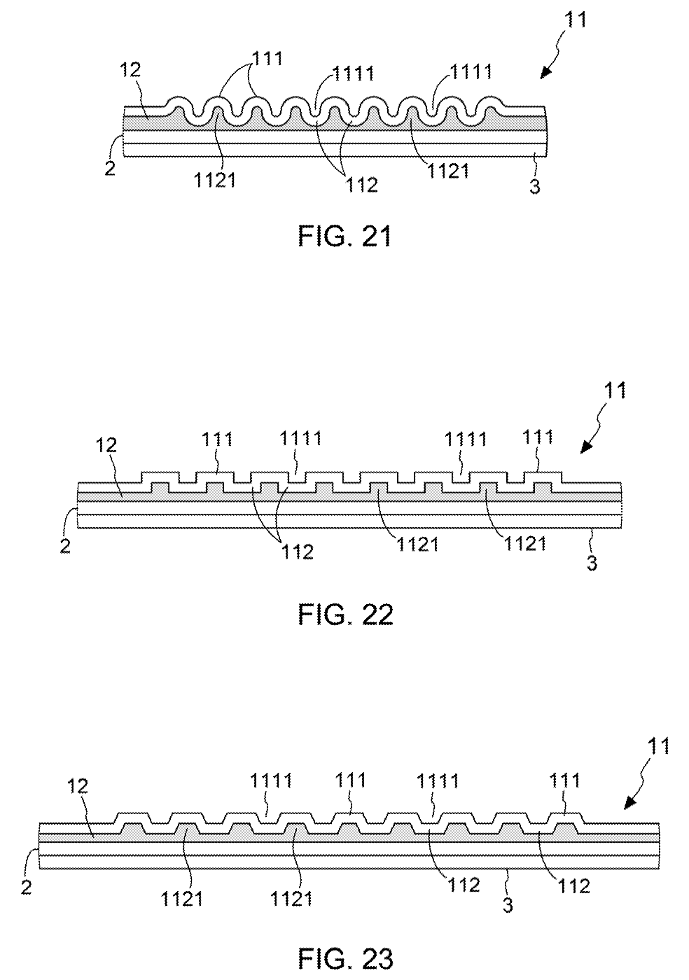

FIG. 20 illustrates a first schematic stereo diagram of the reinforced support sheet 1 according to a third embodiment of the present invention. Moreover, FIG. 21, FIG. 22 and FIG. 23 illustrate first, second and third cross-sectional views of the wrinkle structure 11 shown in FIG. 20. As FIG. 20 and FIG. 21 show, in third embodiment the reinforced support sheet 1 also comprises a substrate 10, N numbers of wrinkle structures 11 formed on the substrate 10 and an adhesive layer 12, of which the adhesive layer 12 is formed with a plurality of convexes thereon. To be more specific, the wrinkle structure 11 comprises a plurality of first protrusions 111 and a plurality of second protrusions 112, of which the plurality of first protrusions 111 is periodically formed on a first surface of the substrate 10, and the plurality of second protrusions 112 is also periodically formed on a second surface of the substrate 10. In addition, the substrate 10 is attached to a first surface of the display panel 2 through the adhesive layer 12, so as to make the N numbers of wrinkle structures 11 oppositely overlap the N numbers of foldable regions of the display panel 2.

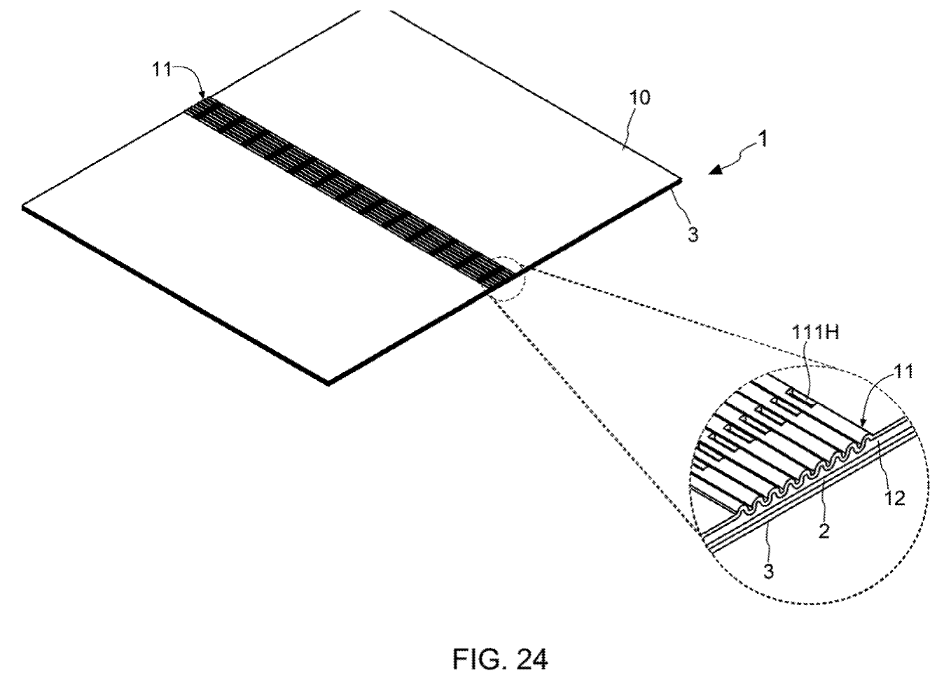

As described in more detail, said protrusion 111 and said second protrusion 112 all have a cross-sectional shape with reference to FIG. 22, FIG. 23, and FIG. 24. In any practicable embodiments, the cross-sectional shape can be, but is not limited to semicircle shape, convex shape, rectangular shape, trapezoid shape, or tapered shape. To be more specific, in third embodiment, the first surface of the substrate 10 and any two said first protrusions 111 enclose a first recess 1111, and the second surface of the substrates 10 and any two said second protrusions 112 enclose a second recess 1121. As such, after the reinforced support sheet 1 is attached to the display panel 2 by the substrate 10 thereof, the plurality of second protrusions 112 are in proximity to the display panel 2, and each of the plurality of convexes of the adhesive layer 12 correspondingly received by one said second recess 1121.

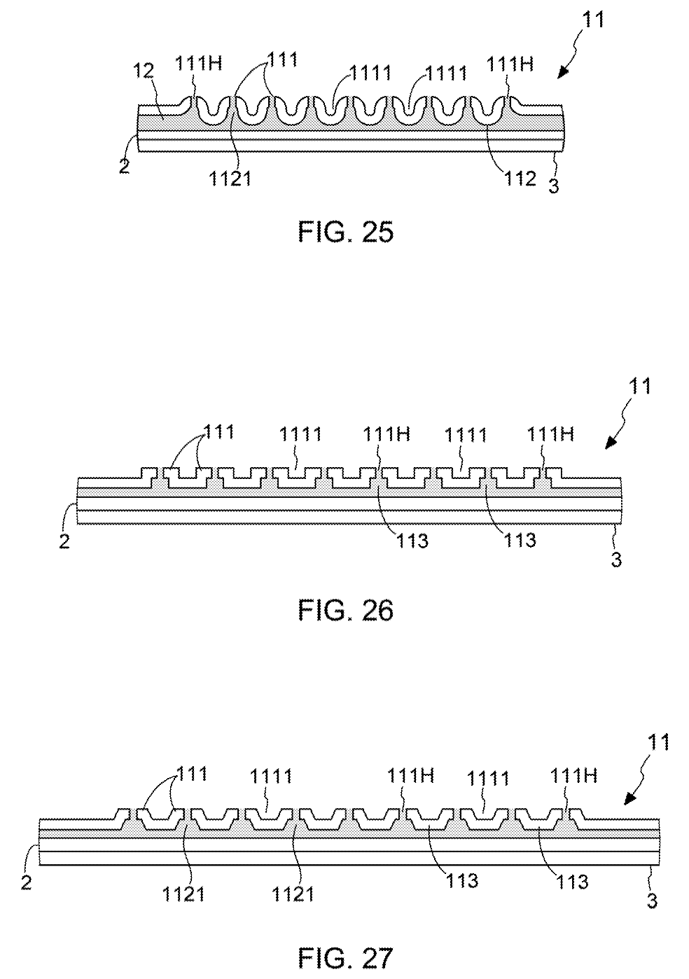

Furthermore, FIG. 24 illustrates a second schematic stereo diagram of the reinforced support sheet 1 according to the third embodiment of the present invention, and FIG. 25, FIG. 26 and FIG. 27 illustrate first, second and third cross-sectional views of the wrinkle structure 11 shown in FIG. 24. As FIG. 24, FIG. 25, FIG. 26, and FIG. 27 show, in third embodiment said protrusion 111 and said second protrusion 112 all have a cross-sectional shape, wherein the cross-sectional shape can be, but is not limited to semicircle shape, convex shape, rectangular shape, trapezoid shape, or tapered shape. In addition, it can also form a plurality of holes 111H on each of the plurality of first protrusions 111. As such, after the substrate 10 is attached to the display panel 2 through the adhesive layer 12, the plurality of convexes of the adhesive layer 12 are received by the plurality of second recess 1121 formed on the second surface of the substrate 10, respectively. Moreover, said convex received by one said second recess 1121 is further embedded in one said hole 111H correspondingly, thereby enhancing the adhesion strength between the substrate 10 and the display panel 2. As a result, adhesive failure is prevented from occurring between the display panel 2 and the reinforced support sheet 1 even if the display panel 2 is repeatedly folded and unfolded.

In another optional embodiment, it is also able to form a plurality of hole on each of the plurality of second protrusions 112. As such, after the substrate 10 is attached to the display panel 2 through the adhesive layer 12, the plurality of convexes of the adhesive layer 12 are received by the plurality of second recess 1121 formed on the second surface of the substrate 10, respectively. Moreover, said convex received by one said second recess 1121 is further embedded in one said hole 1 correspondingly, thereby enhancing the adhesion strength between the substrate 10 and the display panel 2.

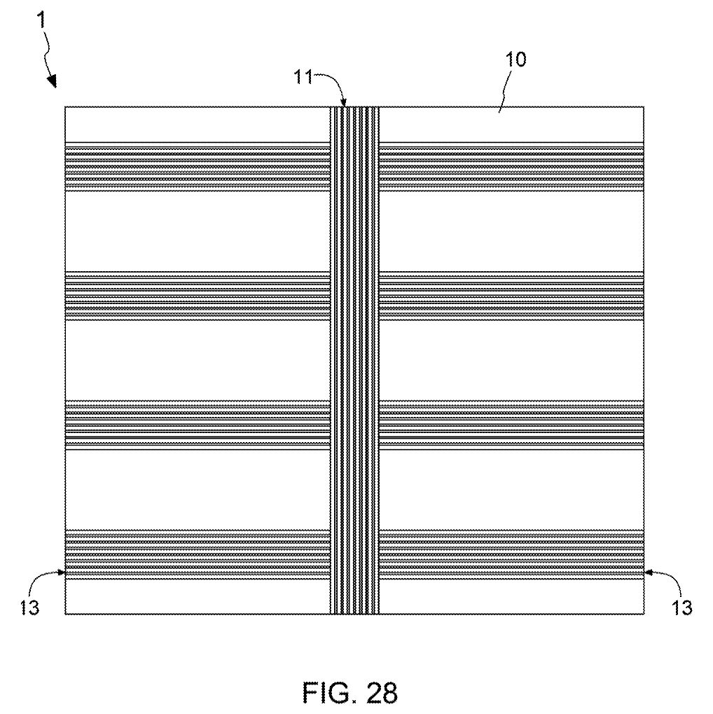

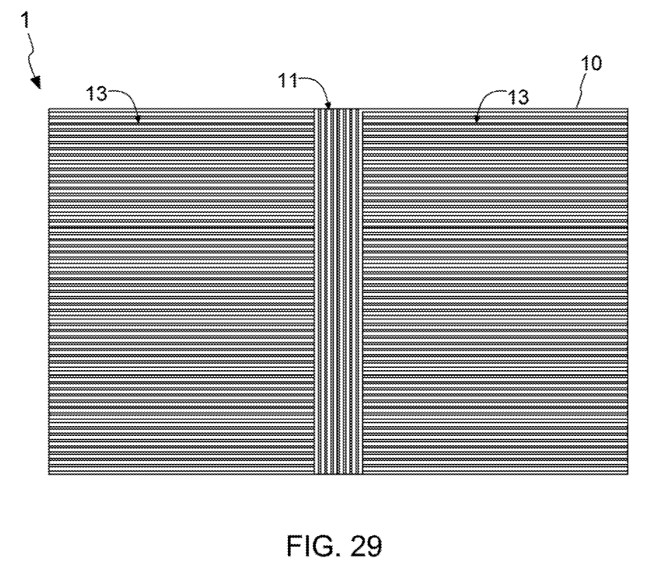

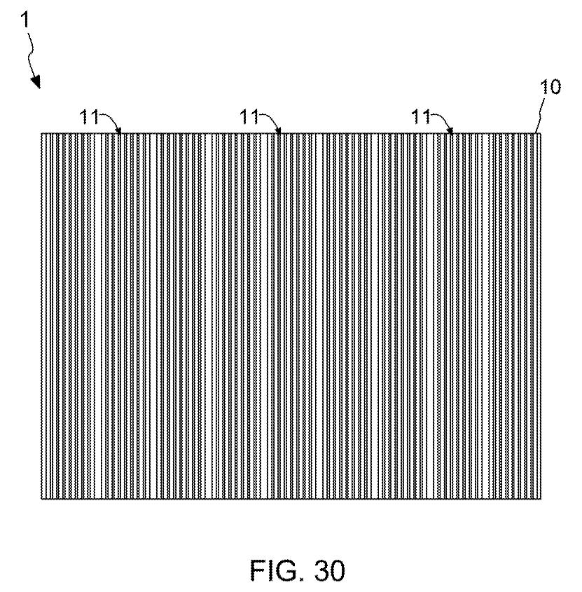

FIG. 28 and FIG. 29 illustrate first and second schematic top views of the reinforced support sheet 1 according to the present invention. As FIG. 28 shows, in one practical application it is able to further form at least two reinforcement wrinkle structures 13 on the substrate 10, so as to surround the N (e.g. N=1 or N=2) numbers of wrinkle structures 11. As such, additional formation of the at least two reinforcement wrinkle structures 13 on the substrate 10 leads the supporting effect of the reinforced support sheet 1 performing on the display panel 2 to be enhanced. In addition, in another optional practical application it can also form a plurality of reinforcement wrinkle structures 13 on the substrate 10, so as to surround the N numbers of wrinkle structures 11. Briefly speaking, the whole region of the substrate 10 is all covered by the plurality of reinforcement wrinkle structures 13 except for N numbers of specific region formed with the N numbers of wrinkle structures 11.

### Fourth embodiment

FIG. 30 illustrates a schematic top view of the reinforced support sheet 1 according to a fourth embodiment of the present invention. It is worth explaining again that, in FIG. 3 there is merely one (i.e., N=1) wrinkle structure 11 formed on the substrate 10, and two (i.e., N=1) wrinkle structures 11 are formed on the substrate 10 with reference to FIG. 4. Specially, according to FIG. 30 it is aware of that, in a special case N numbers of wrinkle structures 11 can be formed on the substrate 10, thereby covering the whole region of the substrate 10.

Therefore, in above descriptions, the reinforced support sheet for integration in a foldable display device according to the present invention has been introduced completely and clearly. To be particularly emphasized that, the above description is made on embodiments of the present invention. However, the embodiments are not intended to limit scope of the present invention, and all equivalent implementations or alterations within the spirit of the present invention still fall within the scope of the present invention.

What is claimed is:

1. A reinforced support sheet, being adapted for integration in a foldable display device for supporting a display panel with N numbers of foldable regions, and comprising:
a substrate, being attached to the display panel through an adhesive layer; and
N numbers of wrinkle structures, being formed on the substrate;
wherein N is a positive integer, and the N numbers of wrinkle structures oppositely overlaps the N numbers of foldable regions;
wherein each of the N numbers of wrinkle structures consists of a plurality of first protrusions humping on a first surface of the substrate and a plurality of second protrusions humping on a second surface of the substrate, and the second surface of the substrate is stuck to the display panel through the adhesive layer;
wherein the substrate and any two said first protrusions enclose a first recess, and the substrate and any two said second protrusions enclose a second recess;
wherein the adhesive layer is formed with a plurality of convexes thereon, and each of the plurality of convexes correspondingly received by one said second recess;
wherein there is a first spacing between the plurality of second protrusions and the display panel in case of the reinforced support sheet being attached to the display panel.

2. The reinforced support sheet of claim 1, wherein said first protrusion and said second protrusion all have a cross-sectional shape selected from a group consisting of semicircle shape, convex shape, rectangular shape, trapezoid shape, and tapered shape.

3. The reinforced support sheet of claim 1, wherein the substrate is fully covered by the N numbers of wrinkle structures.

4. The reinforced support sheet of claim 1, wherein the substrate is made of a metal material, and has a thickness in a range between 10 μm and 60 μm.

5. The reinforced support sheet of claim 1, wherein there is a second spacing between a peak of said first protrusion and the second surface of the display panel, and the second spacing is in a range between 10 μm and 1,000 μm.

6. The reinforced support sheet of claim 1, wherein said first protrusion is provided with a plurality of holes thereon, and said convex received by one said second recess is further embedded in one said hole correspondingly.

7. The reinforced support sheet of claim 1, wherein said second protrusion is provided with a plurality of holes thereon, and said convex that is received by one said second recess is further embedded in one said hole correspondingly.

8. The reinforced support sheet of claim 1, wherein at least two reinforcement wrinkle structures are formed on the substrate, so as to surround the N numbers of wrinkle structures.

9. The reinforced support sheet of claim 1, wherein a plurality of reinforcement wrinkle structures are formed on the substrate, so as to surround the N numbers of wrinkle structures.

10. A reinforced support sheet, being adapted for integration in a foldable display device for supporting a display panel with N numbers of foldable regions, and comprising:
a substrate, being attached to the display panel through an adhesive layer; and
N numbers of wrinkle structures, being formed on the substrate;
wherein N is a positive integer, and the N numbers of wrinkle structures oppositely overlaps the N numbers of foldable regions;
wherein each of the N numbers of wrinkle structures consists of a plurality of first protrusions periodically humping on a first surface of the substrate and a plurality of second protrusions periodically humping on a second surface of the substrate, and the second surface of the substrate is stuck to the display panel through the adhesive layer;
wherein the substrate and any two said first protrusions enclose a first recess, and the substrate and any two said second protrusions enclose a second recess;
wherein the adhesive layer is formed with a plurality of convexes thereon, and each of the plurality of convexes correspondingly received by one said second recess;
wherein the plurality of second protrusions are in proximity to the display panel in case of the reinforced support sheet being attached to the display panel.

11. A reinforced support sheet, being adapted for integration in a foldable display device for supporting a display panel with N numbers of foldable regions, and comprising:
a substrate, being attached to the display panel through an adhesive layer; and
N numbers of wrinkle structures, being formed on the substrate;
wherein N is a positive integer, and the N numbers of wrinkle structures oppositely overlaps the N numbers of foldable regions;
wherein each of the N numbers of wrinkle structures consists of a plurality of first protrusions periodically humping on a first surface of the substrate and a plurality of second protrusions periodically humping on a second surface of the substrate, and the second surface of the substrate is stuck to the display panel through the adhesive layer;
wherein the substrate and any two said first protrusions enclose a first recess, the adhesive layer is formed with a plurality of convexes thereon, and each of the plurality of convexes correspondingly received by one said first recess;
wherein there is a spacing between the second surface of the substrate and the display panel in case of the reinforced support sheet being attached to the display panel.

12. A foldable display device, comprising:
a housing case having a top opening;
a display panel, being accommodated in the housing case, wherein a display area of the display panel is exposed from the housing case through the top opening;
a control circuit module of the display panel, being accommodated in the housing case; and
the reinforced support sheet according to claim 1, being attached to the display panel.

13. A foldable display device, comprising:
a housing case having a top opening;
a display panel, being accommodated in the housing case, wherein a display area of the display panel is exposed from the housing case through the top opening;
a control circuit module of the display panel, being accommodated in the housing case; and
the reinforced support sheet according to claim 10, being attached to the display panel.

14. A foldable display device, comprising:
a housing case having a top opening;
a display panel, being accommodated in the housing case, wherein a display area of the display panel is exposed from the housing case through the top opening;
a control circuit module of the display panel, being accommodated in the housing case; and
the reinforced support sheet according to claim 11, being attached to the display panel.
